(19) United States
(12) Patent Application Publication
(10) Pub. No.: US 2013/0072012 A1
(43) Pub. Date: Mar. 21, 2013

(54) Method For Forming Package Substrate With Ultra-Thin Seed Layer

(71) Applicant: Bo-Yu Tseng, Hsinchu (TW)

(72) Inventor: Bo-Yu Tseng, Hsinchu (TW)

(21) Appl. No.: 13/235,347

(22) Filed: Sep. 16, 2011

(51) Int. Cl. H01L 21/60

(52) U.S. Cl. 438/613; 257/E21.508

(57) ABSTRACT

A method for forming a package substrate with a seed layer is provided, which includes a step of etching away the metal foil laminated on the substrate, so that the substrate has a rough surface, and a step of forming an ultra-thin seed layer on the rough surface of the substrate, wherein the ultra-thin seed layer is formed along the rough surface of the substrate, and thereby the ultra-thin seed layer has a rough surface. Consequently, the adhesion between the metal bumps or circuits formed on the ultra-thin rough seed layer and the substrate can be increased. Furthermore, because the seed layer is ultra thin, the metal bumps or the circuit lines formed on the package substrate can be made finer in line widths and line pitches, and the good yield of the package substrate with fine circuit lines can be increased.

### BACKGROUND OF THE INVENTION

1. Field of the Invention

The present invention relates to a method for forming a package substrate, and more particularly to a method for forming a package substrate with an ultra-thin seed layer for increasing the adhesion between the package substrate and the metal bumps or the circuit lines. Accordingly, the metal bumps or the circuit lines on the package substrate can be made finer in line widths and line pitches because the seed layer is ultra thin.

2. The Prior Arts

In a conventional method for forming package substrate, a 3 to 12 μm of thickness of copper foil is directly bonded to the surface of the substrate as a conductive layer, and followed by photolithography, plating and etching to form the circuits. Then, the dry films and the conductive layer uncovered by the circuits are removed. Recently, the printed circuit boards are developed toward lightweight, thin, short and small size, and high density. Therefore, the demand for finer metal line widths and line pitches is increasing day by day.

If the wiring density of the circuit is high, the metal line widths and metal line pitches need to become smaller. However, the thickness of the copper foil, which is conventionally served as a conductive layer, is between 3 to 12 μm so that the shortening of metal line pitches is restricted, and thereby the wiring density and the good yield of the substrate with fine circuit lines cannot be increased.

### SUMMARY OF THE INVENTION

An objective of the present invention is to provide a method for forming a package substrate with an ultra-thin seed layer, which comprises: laminating a metal foil onto a substrate; forming at least one via hole through the substrate and the metal foil; etching away the metal foil, so that the substrate has a rough surface; forming a seed layer on the rough surface of the substrate and an sidewall of the at least one via hole, the seed layer being made of electrically conductive material; laminating a dry film onto the seed layer wherein the dry film has a plurality of openings exposing a portion of the seed layer and the at least one via hole; plating a metal to fill the at least one via hole and on the portion of the seed layer exposed by the openings of the dry film so as to form at least one metal bump on the portion of the seed layer, and on the at least one via hole filled with the metal; and removing the dry film and the seed layer outside the at least one metal bump, wherein the seed layer is formed along the rough surface of the substrate, so that the seed layer also has a rough surface, and the adhesion of the at least one metal bump and/or the circuits, and the substrate is increased through the rough surface of the seed layer. Furthermore, because the seed layer is ultra thin, the metal bumps or the circuit lines formed on the package substrate can be made finer in line widths and line pitches, and the good yield of the package substrate with fine circuit lines can be increased.

Another objective of the present invention is to provide a method for forming a package substrate with an ultra-thin seed layer, which comprises: laminating a first metal foil and a second metal foil onto a top surface and a bottom surface of the substrate, respectively; forming at least one via hole through the substrate, the first metal foil, and the second metal foil; etching away the first metal foil and the second metal foil, so that the substrate has a rough top surface and a rough bottom surface; forming a seed layer on the rough top surface, the rough bottom surface, and an sidewall of the at least one via hole, the seed layer being made of electrically conductive material; laminating a first dry film onto the seed layer on the rough top surface, and laminating a second dry film onto the seed layer on the rough bottom surface, wherein the first and second dry films each has a plurality of openings exposing a portion of the seed layer and the at least one via hole; plating a metal to fill the at least one via hole and on the portion of the seed layer exposed by the openings of the first and second dry films so as to form at least one metal bump on the portion of the seed layer, and on the at least one via hole filled with the metal; and removing the first and second dry films and the seed layer outside the at least one metal bump to form the package substrate having a double-layer structure, wherein the seed layer is formed along the rough surface of the substrate, so that the seed layer also has a rough surface, and the adhesion of the at least one metal bump and/or the circuits, and the substrate is increased through the rough surface of the seed layer. Furthermore, because the seed layer is ultra thin, the metal bumps or the circuit lines formed on the package substrate can be made finer in line widths and line pitches, and the good yield of the package substrate with fine circuit lines can be increased.

The package substrate of the present invention can have a monolayer, double-layer, or multiple-layer structure.

In the present invention, the ultra-thin seed layer is used in the package substrate instead of the metal foil used in the conventional package substrate. Because the seed layer is ultra thin, the metal bumps or the circuit lines formed on the package substrate can be made finer in line widths and line pitches, and the good yield of the package substrate with fine circuit lines can be increased. Moreover, in the present invention, the seed layer made of electrically conductive material has a rough surface, and thereby the adhesion of the metal bumps and/or the circuits, and the substrate is increased through the rough surface of the seed layer. Therefore, the adhesion problem between some metal materials and the substrate can be solved.

The present invention will become more obvious from the following description when taken in connection with the accompanying drawings which show, for purposes of illustration only, a preferred embodiment in accordance with the present invention.

### BRIEF DESCRIPTION OF THE DRAWINGS

The present invention will become more apparent by describing embodiments thereof in detail with reference to the accompanying drawing in which:

FIGS. 1A to 1H are cross-sectional views illustrating a method of forming a package substrate with an ultra-thin seed layer according to a first embodiment of the present invention;

FIGS. 2A to 2G are cross-sectional views illustrating a method of forming a package substrate with an ultra-thin seed layer according to a second embodiment of the present invention; and

FIGS. 3A to 3H are cross-sectional views illustrating a method of forming a package substrate with an ultra-thin seed layer according to a third embodiment of the present invention.

### DETAILED DESCRIPTION OF THE PREFERRED EMBODIMENTS

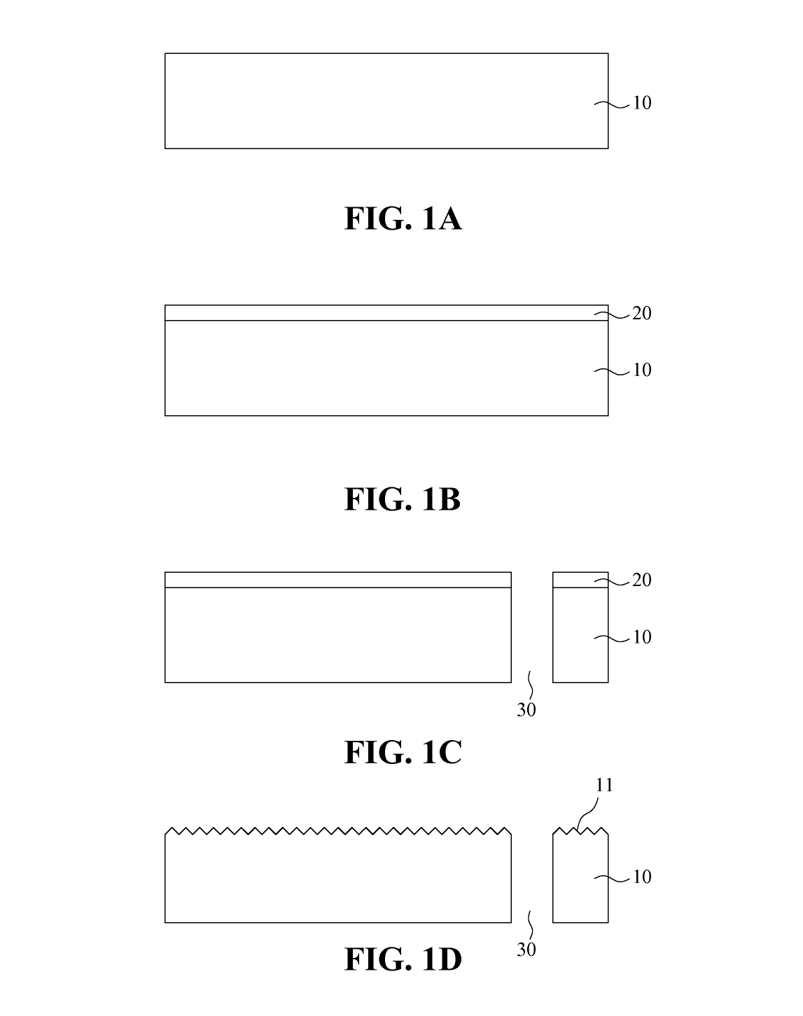

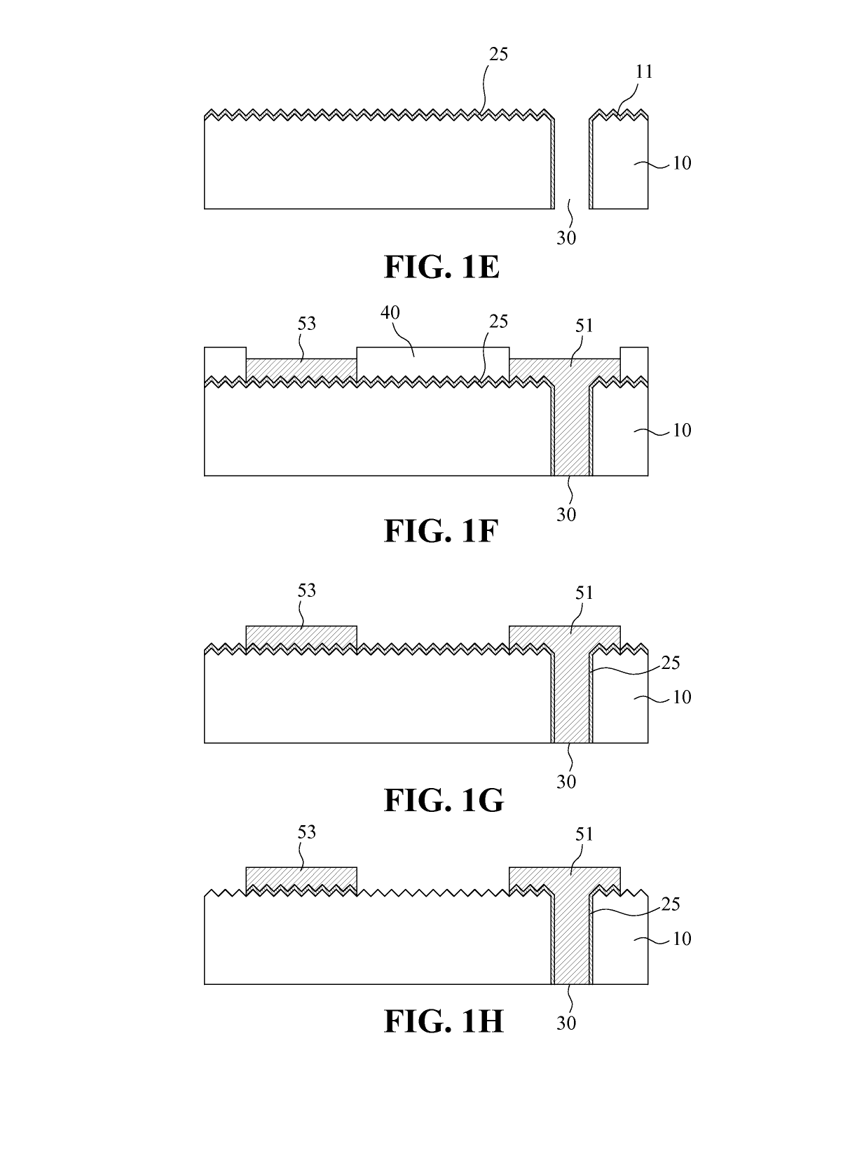

FIGS. 1A to 1H are cross-sectional views illustrating a method of forming a package substrate with an ultra-thin seed layer according to a first embodiment of the present invention. Referring to FIGS. 1A to 1 H, a metal foil 20 is laminated on a surface of a substrate 10. Then, at least one via hole 30 (for example, via hole 30 as shown in FIG. 1C) is formed through the substrate 10 and the metal foil 20. Subsequently, the metal foil 20 is etched away, so that the substrate 10 has a rough surface 11. In other words, when the metal foil 20 is etched away from the substrate 10, the surface of the substrate 10 becomes rough, as shown in FIG. 1D.

Then, an ultra-thin seed layer 25 is formed on the rough surface 11 of the substrate 10 and an sidewall of the at least one via hole 30, and the ultra-thin seed layer 25 is made of electrically conductive material. The ultra-thin seed layer 25 is formed along the rough surface 11 of the substrate 10, and thereby the ultra-thin seed layer 25 also has a rough surface, as shown in FIG. 1E. Then, a dry film 40 is laminated onto the ultra-thin seed layer 25, wherein the dry film 40 has a plurality of openings which expose a portion of the ultra-thin seed layer 25 and the at least one via hole 30.

A metal is plated on the portion of the ultra-thin seed layer 25 exposed by the openings of the dry film 40, and also fills up the at least one via hole 30 so as to form at least one metal bump 53 or 51 on the portion of the ultra-thin seed layer 25 and/or on the at least one via hole filled with the metal, as shown in FIG. 1F, wherein the metal used for plating is, for example, copper or copper alloy. The ultra-thin seed layer 25 is formed along the rough surface 11 of the substrate 10, and thereby the ultra-thin seed layer 25 also has a rough surface. Consequently, the adhesion of the at least one metal bump 53 or 51 and the substrate 10 is increased through the rough surface of the ultra-thin seed layer 25. Then, the dry film 40 and the ultra-thin seed layer 25 outside the at least one metal bump 53 or 51 is removed, as shown in FIGS. 1G to 1H. The rough surface 11 of the substrate 10 is, for example, the rough top surface or rough bottom surface of the substrate 10. The metal foil is, for example, copper foil. The metal bump 53 or 51 is, for example, copper bump. The at least one via hole 30 comprises at least one of a blind via hole, a buried via hole, and a through hole.

The ultra-thin seed layer 25 is formed by one of chemical vapor deposition and plasma sputtering deposition. The thickness of the ultra-thin seed layer 25 is less than 1 μm. Furthermore, because the seed layer is ultra thin, the metal bumps or the circuit lines formed on the package substrate can be made finer in line widths and line pitches, and the good yield of the package substrate with fine circuit lines can be increased.

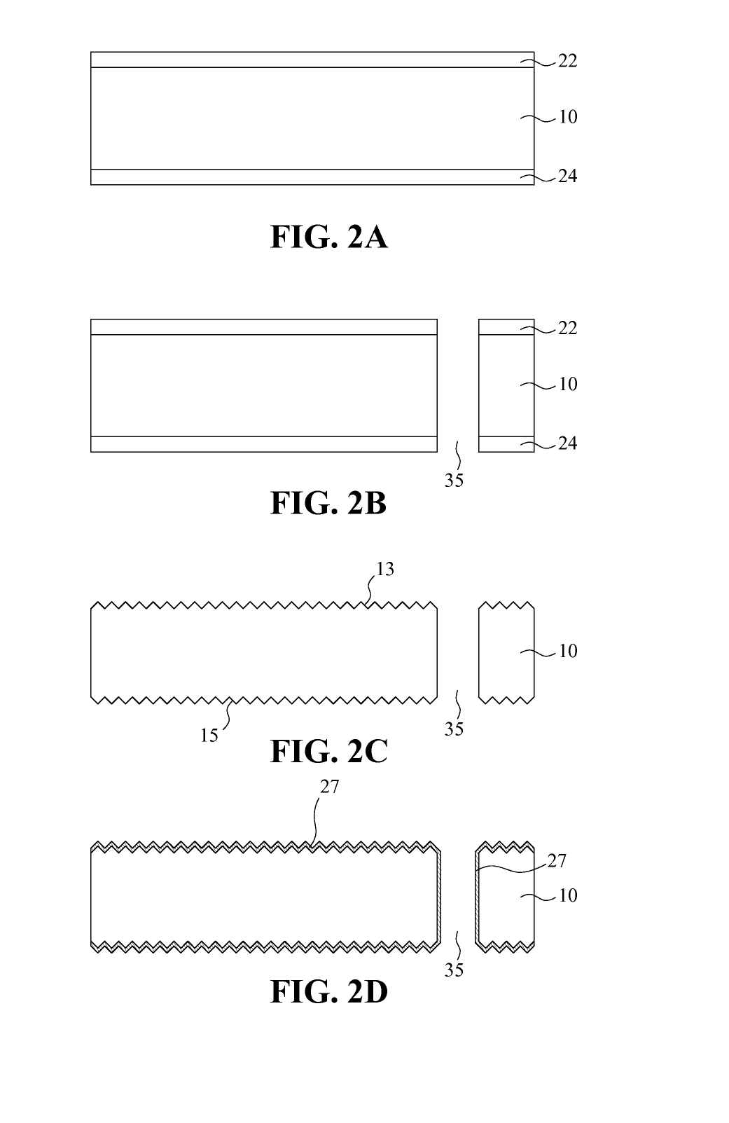

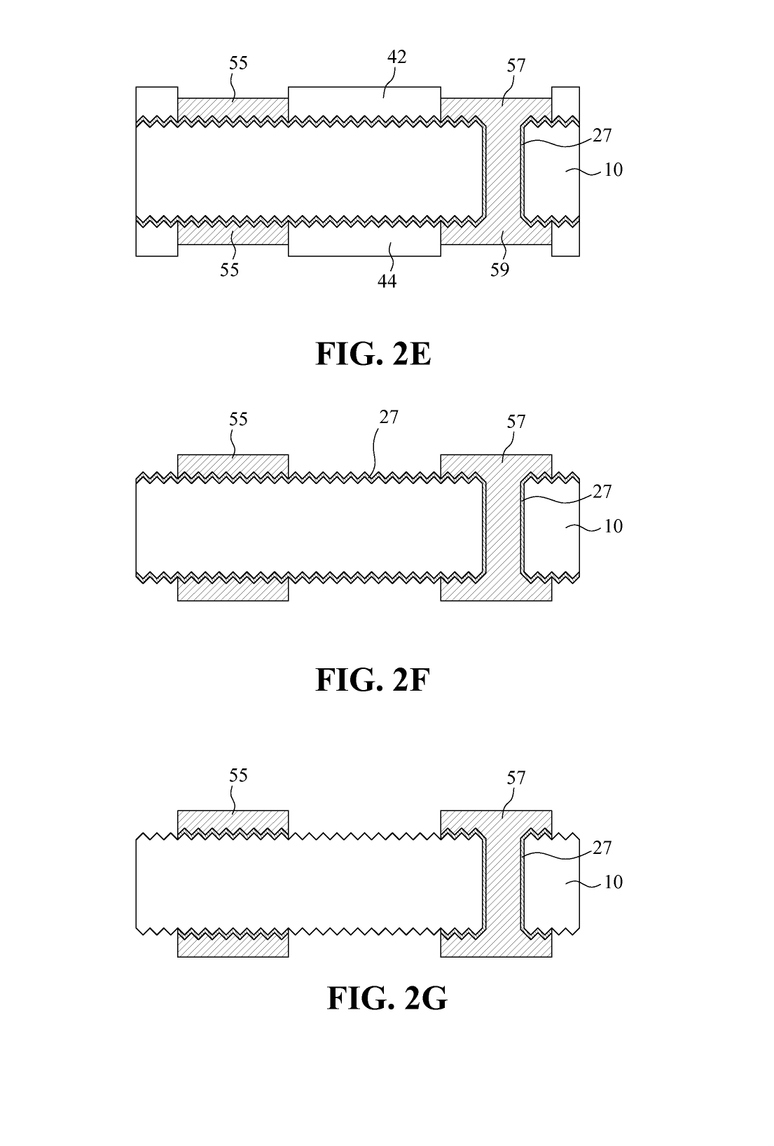

FIGS. 2A to 2G are cross-sectional views illustrating a method of forming a package substrate with an ultra-thin seed layer according to a second embodiment of the present invention. Referring to FIGS. 2A to 2G, a first metal foil 22 and a second metal foil 24 are laminated onto a top surface and a bottom surface of the substrate 10, respectively. Then, at least one via hole 35 (for example, via hole 35 as shown in FIG. 2B) is formed through the substrate 10, the first metal foil 22, and the second metal foil 24. Subsequently, the first metal foil 22 and the second metal foil 24 are etched away, so that the substrate has a rough top surface 13 and a rough bottom surface 15. In other words, when the first metal foil 22 and the second metal foil 24 are etched away from the substrate 10, the top and bottom surfaces 13 and 15 of the substrate 10 become rough, as shown in FIG. 2C.

Then, an ultra-thin seed layer 27 is formed on the rough top surface 13 and the rough bottom surface 15 of the substrate 10, and an sidewall of the at least one via hole 35, and the seed layer 27 is made of electrically conductive material. The ultra-thin seed layer 27 is formed along the rough top and bottom surfaces 13 and 15 of the substrate 10, and thereby the ultra-thin seed layer 27 also has a rough surface, as shown in FIG. 2D. Subsequently, a first dry film 42 is laminated onto the seed layer 27 on the rough top surface 13 of the substrate 10, and a second dry film 44 is laminated onto the seed layer 27 on the rough bottom surface 15 of the substrate 10, wherein the first and second dry films 42 and 44 each has a plurality of openings exposing a portion of the seed layer 27 and the at least one via hole 35.

Then, a metal is plated on the portion of the seed layer 27 exposed by the openings of the first and second dry films 42 and 44, and also fills up the at least one via hole 35 so as to form at least one metal bump 55, 57 or 59 on the portion of the ultra-thin seed layer 27 and/or on the at least one via hole filled with the metal, as shown in FIG. 2E, wherein the metal used for plating is, for example, copper or copper alloy. The ultra-thin seed layer 27 is formed along the rough top and bottom surfaces 13 and 15 of the substrate 10, and thereby the ultra-thin seed layer 27 also has a rough surface. Consequently, the adhesion of the at least one metal bump 55, 57 or 59 and the substrate 10 is increased through the rough surface of the ultra-thin seed layer 27. Then, the first and second dry films 42 and 44, and the ultra-thin seed layer 27 outside the at least one metal bump 55, 57 or 59 is removed so as to form the package substrate having a double-layer structure, as shown in FIGS. 2F to 2G. The first metal foil 22 and the second metal foil 24 are, for example, copper foil. The metal bump 55, 57 or 59 is, for example, copper bump. The at least one via hole 35 comprises at least one of a blind via hole, a buried via hole, and a through hole. The circuit elements formed on the top surface of the package substrate and the circuit elements formed on the bottom surface of the package substrate can be electrically connected with each other via the metal bumps 57 and 59 formed on two ends of the via hole 35 filled with the metal.

The ultra-thin seed layer 27 is formed by one of chemical vapor deposition and plasma sputtering deposition. The thickness of the ultra-thin seed layer 27 is less than 1 μm. Furthermore, because the seed layer is ultra thin, the metal bumps or the circuit lines formed on the package substrate can be made finer in line widths and line pitches, and the good yield of the package substrate with fine circuit lines can be increased.

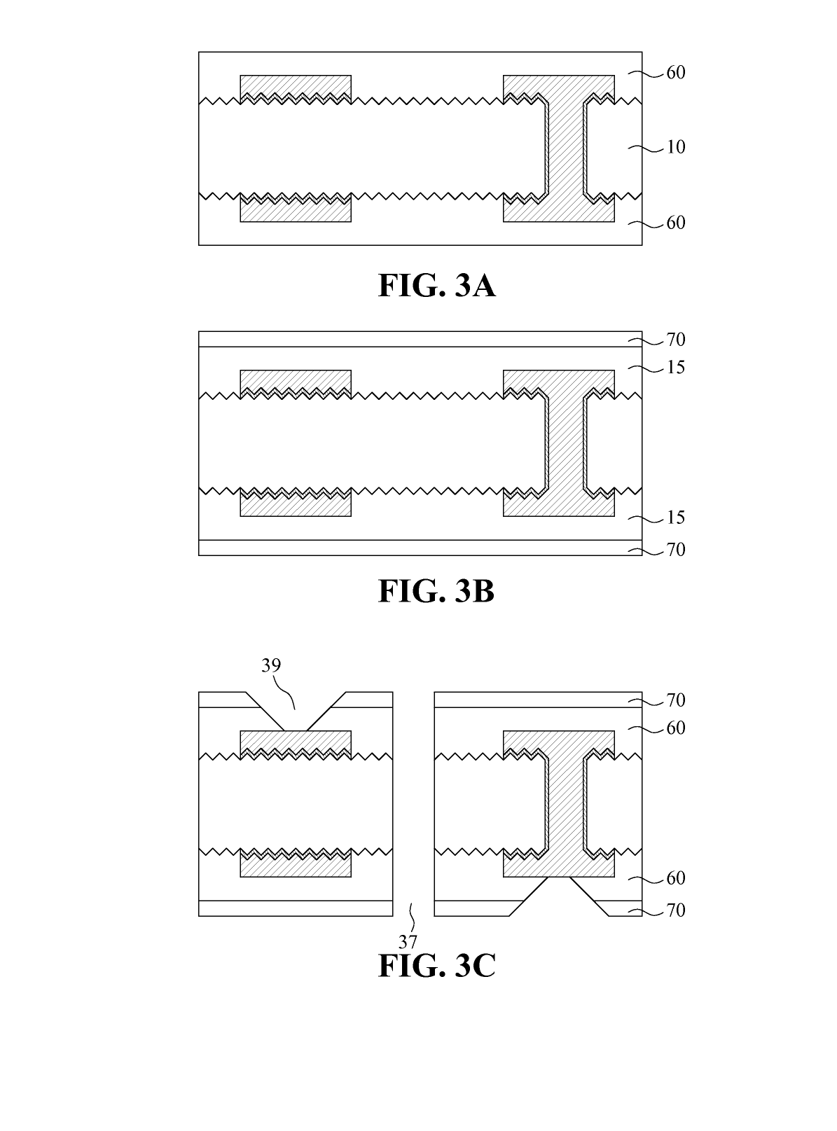

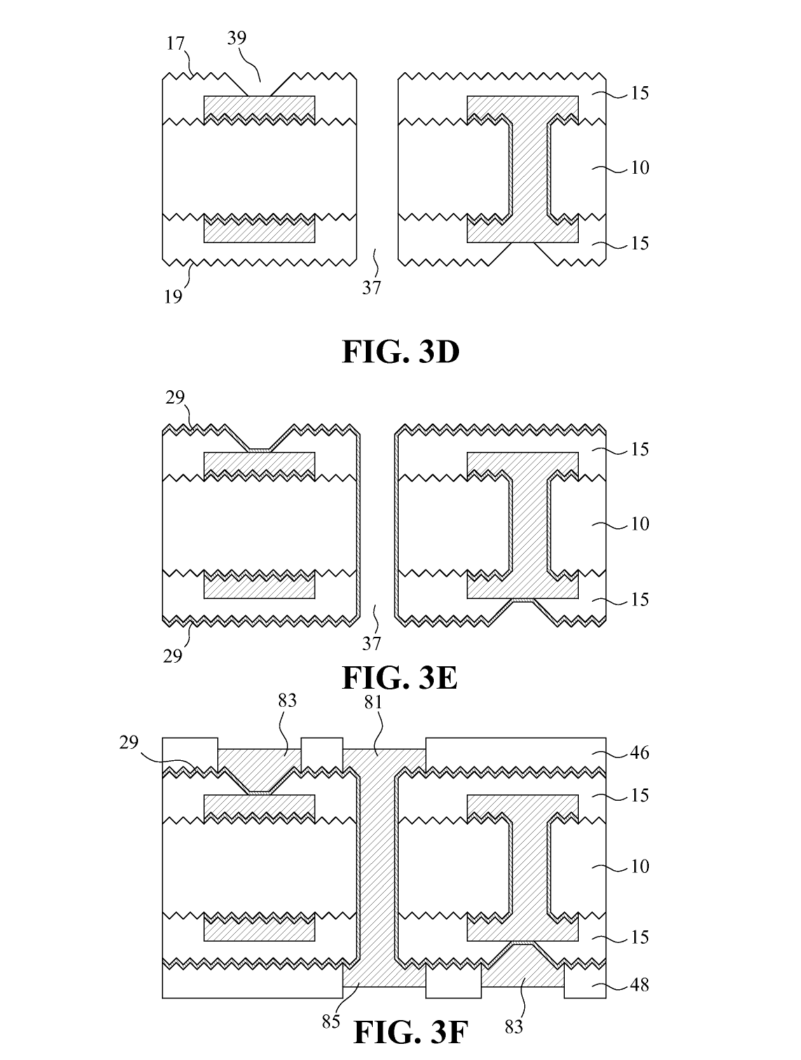

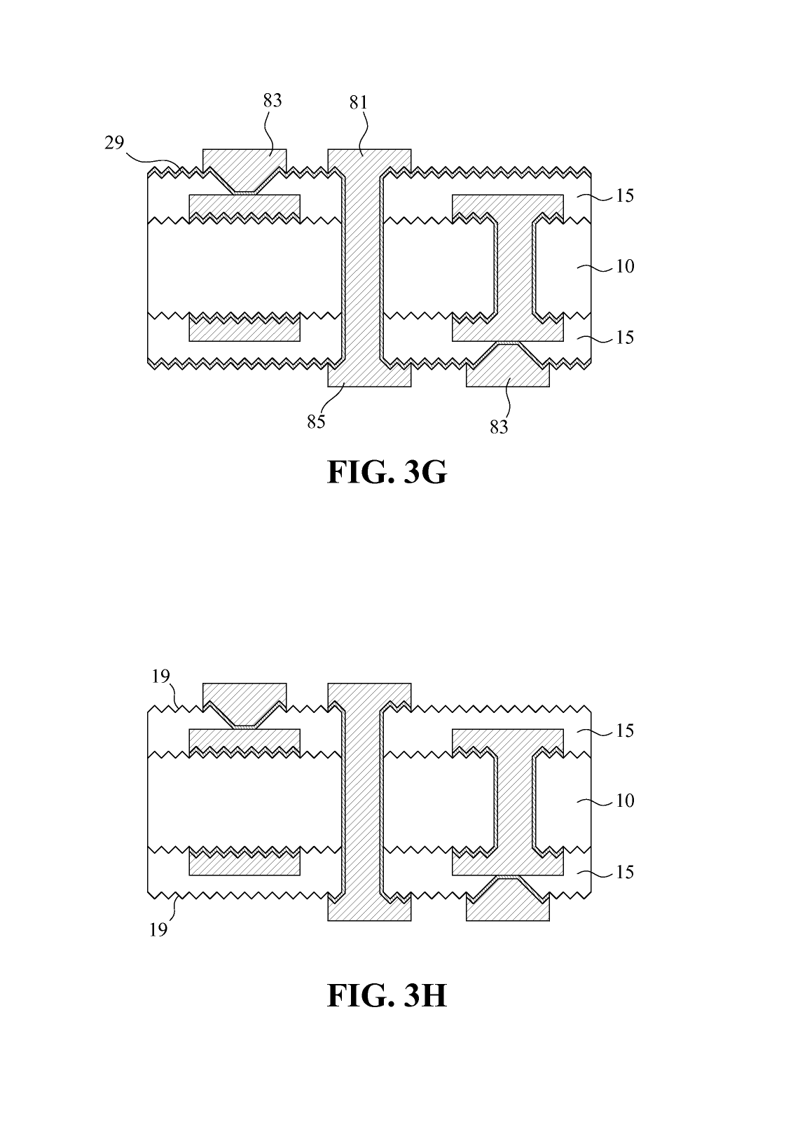

FIGS. 3A to 3H are cross-sectional views illustrating a method of forming a package substrate with an ultra-thin seed layer according to a third embodiment of the present invention. Referring to FIGS. 3A to 3H, two third substrates 60 are respectively formed on the top and bottom of the package substrate having a double-layer structure of the second embodiment of the present invention. Then, two metal foils 70 are respectively laminated onto the two third substrates 60. Subsequently, one through hole 37 is formed through the third substrate 60 and the package substrate of the second embodiment of the present invention, and one buried via hole 39 is formed in the third substrate 60.

Then, the two metal foils 70 are etched away from the third substrate 60, so that the third substrate 60 has a rough top surface 17 and a rough bottom surface 19. Subsequently, a seed layer 29 is formed on the rough top surface 17 and the rough bottom surface 19 of the third substrate 60, and the sidewalls of the through hole 37 and the buried via hole 39, as shown in FIGS. 3D to 3E.

Then, a third dry film 46 is laminated onto the seed layer 29 on the rough top surface 17 of the third substrate 60, and a fourth dry film 48 is laminated onto the seed layer 29 on the rough bottom surface 19 of the third substrate 60, wherein the third and fourth dry films 46 and 48 each has a plurality of openings exposing the through hole 37 and the buried via hole 39. Subsequently, a metal is plated to fill up the through hole 37 and the buried via hole 39 exposed by the openings of the third and fourth dry films 46 and 48 so as to form the metal bumps 81, 83, and 85, as shown in FIG. 3F.

Then, the third and fourth dry films 46 and 48, and the seed layer 29 outside the metal bumps 81, 83, and 85 are removed to form the package substrate having a multiple-layer structure, as shown in FIGS. 3G to 3H. The circuit elements formed on the top surface of the package substrate and the circuit elements formed on the bottom surface of the package substrate can be electrically connected with each other via the metal bumps 81 and 85 formed on two ends of the through hole 37 filled with the metal. The inner circuit elements of the package substrate and the outer circuit elements of the package substrate can be electrically connected with each other via the metal bump 83 formed by filling the buried via hole 39 with the metal.

While we have shown and described the embodiment in accordance with the present invention, it should be clear to those skilled in the art that further embodiments may be made without departing from the scope of the present invention.

What is claimed is:

1. A method for forming a package substrate with a seed layer, comprising:
laminating a metal foil onto a substrate;
forming at least one via hole through the substrate and the metal foil;
etching away the metal foil, so that the substrate has a rough surface;
forming a seed layer on the rough surface of the substrate and an sidewall of the at least one via hole, the seed layer being made of electrically conductive material;
laminating a dry film onto the seed layer wherein the dry film has a plurality of openings exposing a portion of the seed layer and the at least one via hole;
plating a metal to fill the at least one via hole and on the portion of the seed layer exposed by the openings of the dry film so as to form at least one metal bump on the portion of the seed layer, and on the at least one via hole filled with the metal; and
removing the dry film and the seed layer outside the at least one metal bump.

2. The method as claimed in claim 1, wherein the seed layer is formed by one of chemical vapor deposition and plasma sputtering deposition.

3. The method as claimed in claim 1, wherein a thickness of the seed layer is less than 1 μm.

4. The method as claimed in claim 1, wherein the at least one via hole comprises at least one of a blind via hole, a buried via hole, and a through hole.

5. The method as claimed in claim 1, wherein the seed layer is formed along the rough surface of the substrate.

6. A method for forming a package substrate with a seed layer, comprising:
laminating a first metal foil and a second metal foil onto a top surface and a bottom surface of the substrate, respectively;
forming at least one via hole through the substrate, the first metal foil, and the second metal foil;
etching away the first metal foil and the second metal foil, so that the substrate has a rough top surface and a rough bottom surface;
forming a seed layer on the rough top surface, the rough bottom surface, and an sidewall of the at least one via hole, the seed layer being made of electrically conductive material;
laminating a first dry film onto the seed layer on the rough top surface, and laminating a second dry film onto the seed layer on the rough bottom surface, wherein the first and second dry films each has a plurality of openings exposing a portion of the seed layer and the at least one via hole;
plating a metal to fill the at least one via hole and on the portion of the seed layer exposed by the openings of the first and second dry films so as to form at least one metal bump on the portion of the seed layer, and on the at least one via hole filled with the metal; and
removing the first and second dry films and the seed layer outside the at least one metal bump.

7. The method as claimed in claim 6, wherein the seed layer is formed by one of chemical vapor deposition and plasma sputtering deposition.

8. The method as claimed in claim 6, wherein a thickness of the seed layer is less than 1 μm.

9. The method as claimed in claim 6, wherein the at least one via hole comprises at least one of a blind via hole, a buried via hole, and a through hole.

10. The method as claimed in claim 6, wherein the seed layer is formed along the rough top surface and the rough bottom surface.

11. The method as claimed in claim 6, further comprising:
forming a third substrate on a top and/or a bottom of the package substrate of claim 6;
laminating a metal foil onto the third substrate;
forming at least one via hole through the third substrate and the package substrate of claim 6;
etching away the metal foil, so that the third substrate has a rough top surface and a rough bottom surface;
forming a seed layer on the rough top surface and/or the rough bottom surface of the third substrate and an sidewall of the at least one via hole;
laminating a third dry film onto the seed layer on the rough top surface of the third substrate, and laminating a fourth dry film onto the seed layer on the rough bottom surface of the third substrate, wherein the third and fourth dry films each has a plurality of openings exposing a portion of the seed layer and the at least one via hole;
plating a metal to fill the at least one via hole and on the portion of the seed layer exposed by the openings of the third and fourth dry films so as to form at least one metal bump on the portion of the seed layer exposed by the openings of the third and fourth dry films, and on the at least one via hole filled with the metal; and
removing the third and fourth dry films and the seed layer outside the at least one metal bump on the third substrate.

12. The method as claimed in claim 11, wherein the seed layer is formed along the rough top surface and the rough bottom surface of the third substrate.
